(19) United States
(12) Patent Application Publication
(10) Pub. No.: US 2022/0116017 A1
(43) Pub. Date: Apr. 14, 2022

(54) ACOUSTIC WAVE DEVICE

(71) Applicant: Murata Manufacturing Co., Ltd., Nagaokakyo-shi (JP)

(72) Inventor: Sunao YAMAZAKI, Nagaokakyo-shi (JP)

(21) Appl. No.: 17/556,222

(22) Filed: Dec. 20, 2021

Related U.S. Application Data
(63) Continuation of application No. PCT/JP2020/018287, filed on Apr. 30, 2020.

(30) Foreign Application Priority Data
Jun. 24, 2019 (JP) 2019-116419

(51) Int. Cl. H03H 9/25; H03H 9/145; H01L 41/047; H03H 3/08; H03H 9/10

(52) U.S. Cl. CPC H03H 9/25; H03H 9/14541; H03H 9/1071; H03H 3/08; H01L 41/0475

(57) ABSTRACT

An acoustic wave device includes first and second acoustic wave resonator units. In a first IDT electrode of the first acoustic wave resonator unit, an intersecting width region includes a central region and first and second low acoustic velocity regions at outer side portions of the central region. The first and second high acoustic velocity regions include openings along an acoustic wave propagation direction. In the second acoustic wave resonator unit, a second IDT electrode includes a central region and first and second low acoustic velocity regions at outer side portions in an intersecting width direction of the central region. At an outer side portion of the first low acoustic velocity region, openings are at a third busbar. At an outer side portion of the second low acoustic velocity region, openings are not provided for a fourth busbar.

### CROSS REFERENCE TO RELATED APPLICATIONS

This application claims the benefit of priority to Japanese Patent Application No. 2019-116419 filed on Jun. 24, 2019 and is a Continuation Application of PCT Application No. PCT/JP2020/018287 filed on Apr. 30, 2020. The entire contents of each application are hereby incorporated herein by reference.

### BACKGROUND OF THE INVENTION

### 1. Field of the Invention

The present invention relates to an acoustic wave device using a piston mode, and particularly, to an acoustic wave device in which an acoustic wave resonator is divided into a plurality of acoustic wave resonator units.

### 2. Description of the Related Art

In International Publication No. WO2015/098678, an acoustic wave resonator is divided in series into first and second acoustic wave resonator units. In International Publication No. WO2015/098678, in the first and second acoustic wave resonator units, an intersecting width region of an IDT electrode includes a central region, and first and second low acoustic velocity regions located on both sides of the central region. First and second high acoustic velocity regions are provided at outer side portions of the first and second low acoustic velocity regions. In order to increase acoustic velocity in the first and second high acoustic velocity regions, openings are provided in busbars. One of the busbars is shared by the first acoustic wave resonator unit and the second acoustic wave resonator unit.

In the acoustic wave device described in International Publication No. WO2015/098678, the first acoustic wave resonator unit and the second acoustic wave resonator unit have the same configuration. Therefore, the frequency position of a transverse mode generated in the first acoustic wave resonator unit and the frequency position of a transverse mode generated in the second acoustic wave resonator unit overlap each other. As a result, the transverse modes strengthen each other, and a transverse mode ripple may not be sufficiently suppressed.

### SUMMARY OF THE INVENTION

Preferred embodiments of the present invention provide acoustic wave devices that are each able to more effectively reduce or prevent a ripple caused by a transverse mode.

An acoustic wave device according to a preferred embodiment of the present invention includes first and second acoustic wave resonator units.

An acoustic wave device of a preferred embodiment of the present invention includes, a piezoelectric substrate, a first IDT electrode on the piezoelectric substrate and defining the first acoustic wave resonator unit, a second IDT electrode on the piezoelectric substrate and defining the second acoustic wave resonator unit electrically connected to the first acoustic wave resonator unit, and an inter-stage connection portion connecting the first acoustic wave resonator unit and the second acoustic wave resonator unit, in which the first IDT electrode includes a first busbar, a second busbar spaced apart from the first busbar, a plurality of first electrode fingers that extend toward the second busbar and include one ends connected to the first busbar, and a plurality of second electrode fingers that extend toward the first busbar and include one ends connected to the second busbar, the second IDT electrode includes a third busbar, a fourth busbar spaced apart from the third busbar, a plurality of third electrode fingers that extend toward the fourth busbar and include one ends connected to the third busbar, and a plurality of fourth electrode fingers that extend toward the third busbar and include one ends connected to the fourth busbar, in each of the first and second IDT electrodes, a central region is provided in a central portion of a direction in which the first and second electrode fingers or the third and fourth electrode fingers extend, first and second low acoustic velocity regions in which an acoustic velocity is low compared to the central region are at both outer side portions of the central region in the direction in which the first and second electrode fingers or the third and fourth electrode fingers extend, first and second high acoustic velocity regions in which acoustic velocity is high compared to the central region are at both outer side portions of the first and second low acoustic velocity regions in the direction in which the first and second electrode fingers or the third and fourth electrode fingers extend, in the first and second high acoustic velocity regions in the first IDT electrode, a plurality of openings along an acoustic wave propagation direction are provided for both the first and second busbars, of the third and fourth busbars in the second IDT electrode, in the first high acoustic velocity region of the third busbar, a plurality of openings along the acoustic wave propagation direction are provided, and in the fourth busbar, the openings are not provided in the second high acoustic velocity region.

In the acoustic wave device according to the above-described preferred embodiment of the present invention, it is possible to sufficiently reduce or prevent a ripple caused by a transverse mode.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a plan view illustrating an electrode structure of an acoustic wave device according to a first preferred embodiment of the present invention.

FIG. 2 is a schematic plan view of the acoustic wave device according to the first preferred embodiment of the present invention.

FIG. 3 is a schematic elevational cross-sectional view describing a piezoelectric substrate of the acoustic wave device according to the first preferred embodiment of the present invention.

FIG. 4 is a diagram illustrating return loss characteristics of the acoustic wave devices according to an example of a preferred embodiment of the present invention and a comparative example.

FIG. 5 is a diagram illustrating impedance characteristics as resonators of the acoustic wave devices of the example of a preferred embodiment of the present invention and the comparative example.

FIG. 6 is a circuit diagram of a ladder filter in which the acoustic wave device according to the first preferred embodiment of the present invention is included.

FIG. 7 is a diagram illustrating attenuation-frequency characteristics of the ladder filters of the example and the comparative example.

FIG. 8 is a diagram illustrating the attenuation-frequency characteristics of the ladder filter of the comparative example and the attenuation-frequency characteristics shifted upward by 5 MHz.

### DETAILED DESCRIPTION OF THE PREFERRED EMBODIMENTS

Hereinafter, the present invention will be clarified by describing specific preferred embodiments of the present invention with reference to the accompanying drawings.

Each of the preferred embodiments described in this specification is merely examples, and it is possible to partially replace or combine configurations between different preferred embodiments.

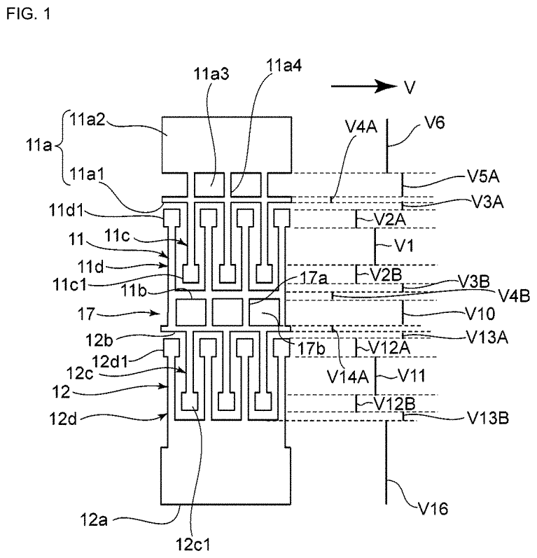

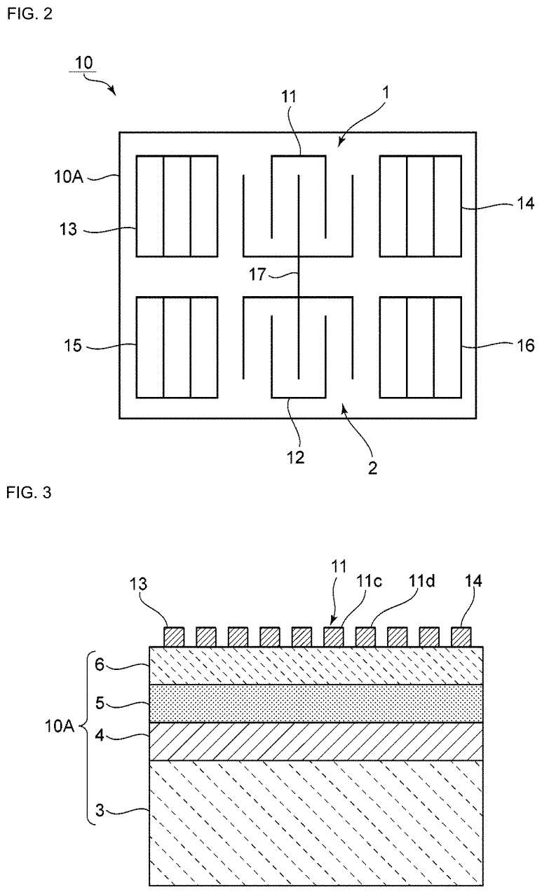

FIG. 1 is a plan view illustrating an electrode structure of an acoustic wave device according to a first preferred embodiment of the present invention, and FIG. 2 is a schematic plan view of the acoustic wave device according to the present preferred embodiment.

The acoustic wave device 10 is configured by dividing an acoustic wave resonator into first and second acoustic wave resonator units 1 and 2 in series.

As illustrated in FIG. 2, the first acoustic wave resonator unit 1 and the second acoustic wave resonator unit 2 are provided on a piezoelectric substrate 10A. The first acoustic wave resonator unit 1 includes a first IDT electrode 11, and reflectors 13 and 14 disposed on both sides of the first IDT electrode 11 in an acoustic wave propagation direction. The second acoustic wave resonator unit 2 includes a second IDT electrode 12, and reflectors 15 and 16 disposed on both sides of the second IDT electrode 12 in the acoustic wave propagation direction. The first acoustic wave resonator unit 1 and the second acoustic wave resonator unit 2 are connected in series by a common busbar 17 that also define and function as an inter-stage connection portion. As described above, the first and second acoustic wave resonator units 1 and 2 are one port acoustic wave resonator units.

As illustrated in FIG. 1, the first IDT electrode 11 includes a first busbar 11a and the common busbar 17 as a second busbar. The first busbar 11a includes an inner busbar portion 11a1, an outer busbar portion 11a2, and a linking portion 11a4 connecting the inner busbar portion 11a1 and the outer busbar portion 11a2. In the first busbar 11a, a plurality of openings 11a3 are disposed along the acoustic wave propagation direction. A portion between the adjacent openings 11a3 and 11a3 is a linking portion 11a4.

One ends of a plurality of first electrode fingers 11c are connected to the inner busbar portion 11a1. The first electrode fingers 11c extend toward the common busbar 17 as the second busbar. One ends of a plurality of second electrode fingers 11d are connected to the common busbar 17. The second electrode fingers 11d extend toward the first busbar 11a side. The plurality of first electrode fingers 11c and the plurality of second electrode fingers 11d are interdigitated with each other. When the first electrode fingers 11c and the second electrode fingers 11d are viewed along the acoustic wave propagation direction, an overlapping region is an intersecting width region. The dimension of the intersecting width region along the direction in which the first and second electrode fingers 11c and 11d extend is the intersecting width.

The tips of the plurality of first electrode fingers 11c and second electrode fingers 11d are provided with wider width portions 11c1 and 11d1 where width of the electrode fingers is thick. Accordingly, the intersecting width region includes a central region and first and second low acoustic velocity regions located on both sides of the central region. A region in which the above-described wider width portion 11d1 is disposed along the acoustic wave propagation direction is the first low acoustic velocity region. A region in which the wider width portion 11c1 is disposed along the acoustic wave propagation direction is the second low acoustic velocity region.

As illustrated in FIG. 1, the common busbar 17 includes a first busbar portion lib and a second busbar portion 12b. One ends of the second electrode fingers 11d are connected to the first busbar portion 11b. Also in the common busbar 17, a plurality of openings 17b are provided along the acoustic wave propagation direction. A portion between adjacent openings 17b is a linking portion 17a. The first busbar portion 11b and the second busbar portion 12b are connected by the linking portion 17a.

On the other hand, in the second IDT electrode 12, the common busbar 17 as a third busbar and a fourth busbar 12a are provided. One ends of a plurality of third electrode fingers 12c are connected to the second busbar portion 12b of the common busbar defining and functioning as the third busbar. The third electrode fingers 12c extend toward the fourth busbar 12a side. One ends of a plurality of fourth electrode fingers 12d are connected to the fourth busbar 12a. The fourth electrode fingers 12d extend toward the common busbar 17 side as the third busbar. The plurality of third electrode fingers 12c and the plurality of fourth electrode fingers 12d are interdigitated with each other. Also in the second IDT electrode 12, wider width portions 12c1 and 12d1 are provided at the tips of the third electrode fingers 12c and the fourth electrode fingers 12d. Thus, the first and second low acoustic velocity regions are provided. That is, a region passing through the wider width portion 12d1 and extending in the acoustic wave propagation direction is the first low acoustic velocity region, and a region passing through the wider width portion 12c1 and extending in the acoustic wave propagation direction is the second low acoustic velocity region. The intersecting width region includes the central region, and the above first and second low acoustic velocity regions located at both sides of the central region.

In the second IDT electrode 12, the common busbar 17, that is, the third busbar is provided with a plurality of openings 17b, and a region passing through the plurality of openings 17b and extending in the acoustic wave propagation direction is a high acoustic velocity region. However, an opening is not provided in the fourth busbar 12a.

The plurality of openings 11a3 may or may not be entirely surrounded by the inner busbar portion 11a1, the outer busbar portion 11a2, and the linking portions 11a4. Similarly, the plurality of openings 17a may or may not be entirely surrounded by the first busbar portion 11b, the second busbar portion 12b, and the linking portions 17a.

As shown in FIG. 1, each of the openings 11a3 is entirely surrounded by the inner busbar portion 11a1, the outer busbar portion 11a2, and the linking portions 11a4, and each of the openings 17a is entirely surrounded by the first busbar portion 11b, the second busbar portion 12b, and the linking portions 17a. However, the inner busbar portion 11a1 may be chipped or cut such that one or more of the openings 11a2 and a gap region (at V3A) are connected. Similarly, the first busbar portion 11b may be chipped or cut such that one or more of the openings 17a and a gap region (at V3B) are connected, and/or the second busbar portion 12b may be chipped or cut such that one or more of the openings 17a and a gap region (at V13A).

The above first and second IDT electrodes 11 and 12, and the reflectors 13, 14, 15, and 16 are provided on the piezoelectric substrate 10A.

As illustrated in FIG. 3, the piezoelectric substrate 10A includes a support substrate 3, a high acoustic velocity member 4, a low acoustic velocity film 5, and a piezoelectric film 6. That is, the high acoustic velocity member 4 and the low acoustic velocity film 5 are laminated between the support substrate 3 and the piezoelectric film 6. Although the material of the support substrate 3 is not particularly limited, for example, a semiconductor such as silicon, or an insulator such as Al₂O₃ can be used.

The high acoustic velocity member 4 is made of a high acoustic velocity material. The high acoustic velocity material refers to a material in which the acoustic velocity of a propagating bulk wave is higher than the acoustic velocity of a propagating acoustic wave through the piezoelectric film 6. As such a high acoustic velocity material, various materials such as, for example, aluminum oxide, silicon carbide, silicon nitride, silicon oxynitride, silicon, sapphire, lithium tantalate, lithium niobate, crystal, alumina, zirconia, cordierite, mullite, steatite, forsterite, magnesia, a diamond-like carbon (DLC) film or diamond, a medium including any of the above materials as a main component, and a medium including a mixture of any of the above materials as a main component can be used.

The low acoustic velocity film 5 is made of a low acoustic velocity material. The low acoustic velocity material refers to a material in which the acoustic velocity of a propagating bulk wave is lower than the acoustic velocity of a bulk wave propagating through the piezoelectric film 6. As the low acoustic velocity material, various materials such as, for example, silicon oxide, glass, silicon oxynitride, tantalum oxide, a compound obtained by adding fluorine, carbon, boron, hydrogen, or a silanol group to silicon oxide, and a medium including any of the above materials as a main component can be used.

The piezoelectric film 6 is made of, for example, LiTaO₃. However, the material of the piezoelectric film 6 is not limited to the above-mentioned materials, and other piezoelectric single crystals may be used. Examples of such a piezoelectric single crystal include Ta₂O₅ and AlN.

In the above-described piezoelectric substrate 10A, energy of the acoustic wave can be effectively confined in the piezoelectric film 6, and a Q value can be increased.

However, the support substrate 3 and the high acoustic velocity member 4 may be integrated. That is, when the support substrate 3 is made of the high acoustic velocity material, the high acoustic velocity member 4 may be omitted.

Alternatively, the piezoelectric substrate 10A not including the low acoustic velocity film 5 may be used.

Furthermore, the piezoelectric substrate 10A is not limited to the above-described structure, and may have a structure in which an acoustic reflection film is provided below the piezoelectric film 6. The acoustic reflection film may be made by laminating a low acoustic impedance film and a high acoustic impedance film.

Further, the piezoelectric substrate 10A may be made of the piezoelectric single crystal.

In the acoustic wave device 10, the transverse mode is reduced or prevented by providing the first and second low acoustic velocity regions on both sides of the intersecting width region and further providing the first and second high acoustic velocity regions at an outer side portion of the intersecting width region. The acoustic wave device 10 includes a feature that the structure to reduce or prevent the transverse mode in the first acoustic wave resonator unit 1 is different from the structure to reduce or prevent the transverse mode in the second acoustic wave resonator unit 2. This will be described more specifically below.

On the right side of FIG. 1, the acoustic velocity in each region is illustrated. As indicated by an arrow V in FIG. 1, the acoustic velocity increases toward the right side in FIG. 1.

In the first IDT electrode 11, the acoustic velocity in the central region of the central intersecting width region is V1, and the acoustic velocities in the first and second low acoustic velocity regions are V2A and V2B. V1 is larger than V2A and V2B. The acoustic velocity in a gap region at an outer side portion of the first low acoustic velocity region is V3A, the acoustic velocity in the portion where the inner busbar portion 11a1 is provided is V4A, the region where the openings 11a3 are provided is V5A, and the acoustic velocity in the outer busbar portion 11a2 is V6. In this case, the acoustic velocity V5A in the region where the plurality of openings 11a3 are provided and the acoustic velocity V6 in the outer busbar portion 11a2 are high. The regions of the acoustic velocity V5A and the acoustic velocity V6 are the first high acoustic velocity region. On the other hand, the regions of the acoustic velocity V2A, the acoustic velocity V3A, and the acoustic velocity V4A define a first low acoustic velocity region. That is, the wider width portion 11d1, the gap region, and the inner busbar portion 11a1 define the first low acoustic velocity region. The acoustic velocity in the first high acoustic velocity region is sufficiently higher than the acoustic velocity in the first low acoustic velocity region. Therefore, the transverse mode can be effectively reduced or prevented.

Also on the second low acoustic velocity region side, the second low acoustic velocity region and the second high acoustic velocity region are located at outer side portions of the central region in a direction in which the first and second electrode fingers 11c and 11d extend. That is, the acoustic velocity in the wider width portion 11c1 is V2B, the acoustic velocity at an outer side portion of the gap region is V3B, the acoustic velocity in the first busbar portion 11b is V4B, and the acoustic velocity in the region where the plurality of openings 17b are provided is V10. Here, the second low acoustic velocity region is the region in which the wider width portion 11c1 is provided, a gap region, and the region in which the first busbar portion 11b is provided. A region where the plurality of openings 17b are provided is a second high acoustic velocity region. Therefore, the ripple due to the transverse mode can also be reduced or prevented in the second low acoustic velocity region side.

On the other hand, the acoustic velocity of a region of the second IDT electrode 12 that includes the wider width portion 12d1 and extends in the acoustic wave propagation direction is V12A, and the common busbar 17 is located at an outer side portion of this region. As described above, the common busbar 17 is shared by the first IDT electrode 11 and the second IDT electrode 12. The common busbar 17 is a second busbar of the first IDT electrode 11, and is a third busbar of the second IDT electrode 12.

In the second IDT electrode 12, a region in which the wider width portion 12d1 is provided, a gap region at an outer side portion of the wider width portion 12d1, and the second busbar portion 12b are first low acoustic velocity regions. That is, a region of the acoustic velocity V12A, a region of the acoustic velocity V13A, and a region of the acoustic velocity V14A define the first low acoustic velocity region. A region where the openings 17b in the common busbar 17 is provided is the first high acoustic velocity region. That is, the first high acoustic velocity region of the acoustic velocity V10 is provided. A sufficient acoustic velocity difference can be ensured between the acoustic velocity V10 of the first high acoustic velocity region and the first low acoustic velocity region. Therefore, the transverse mode can be reduced or prevented.

On the other hand, the acoustic velocity in the second low acoustic velocity region where the wider width portion 12c1 is disposed is V12B, which is lower than the acoustic velocity V11 in the central region. Further, at an outer side portion of the second low acoustic velocity region, the acoustic velocity in the gap region is V13B, and the acoustic velocity in the fourth busbar 12a is V16, both being a high acoustic velocity. That is, the gap region and the fourth busbar 12a define the second high acoustic velocity region.

The acoustic velocity in the second high acoustic velocity region is higher, compared to the acoustic velocity V12B in the second low acoustic velocity region. Note that the acoustic velocity V16 in the fourth busbar 12a is lower than the acoustic velocity V13B. However, since each of the regions of the acoustic velocity V13B and the V16 is present at an outer side portion of the second low acoustic velocity region of the above acoustic velocity V12B, the transverse mode can be reduced or prevented, although not as much as that on the first low acoustic velocity region side.

In addition, in the acoustic wave device 10, since the first acoustic wave resonator unit 1 and the second acoustic wave resonator unit 2 have different structures to reduce or prevent the transverse mode, the frequency position of the transverse mode generated in the first acoustic wave resonator unit 1 is different from the frequency position of the transverse mode generated in the second acoustic wave resonator unit 2. Therefore, since it is difficult for the two units to strengthen each other, the ripple in the transverse mode can be effectively reduced or prevented as a whole. This will be described with reference to the following example.

An example of the acoustic wave device 10 according to the above-described preferred embodiment was designed with the following specifications.

Details of the Piezoelectric Substrate 10A

Support substrate 3: Si

High acoustic velocity member 4: an SiN film with a thickness of about 900 nm

Low acoustic velocity film 5: an SiO₂ film with a thickness of about 673 nm

Piezoelectric film 6: an LT film with a thickness of 600 nm and cut-angles of about 42°

Details of the first and second IDT electrodes 11 and 12, and the reflectors 13 to 16

Wavelength λ determined by an electrode finger pitch=about 2.3 μm

Electrode finger intersecting width in the first and second IDT electrodes 11 and 12=about 7λ

Dimension of the central region along the intersecting width direction=about 6λ

Dimension along the intersecting width direction in the wider width portions 11c1, 11d1, 12c1, and 12d1=about 0.5λ

Number of pairs of electrode fingers of the first and second IDT electrodes 11 and 12=248 pairs

Number of electrode fingers in the reflectors 13 to 16=20 for each

Electrode material: an AlCu film with a thickness of about 100 nm

Width of the gap region in the first IDT electrode 11=about 0.27 μm

Note that the width refers to the dimension of the gap region along the direction in which the first and second electrode fingers 11c and 11d extend, that is, the dimension along the intersecting width direction.

Width of the inner busbar portion 11a1=about 0.3λ

Dimension of the opening 11a3 along the intersecting width direction=about 2λ

Width of the first busbar portion lib and the second busbar portion 12b in the common busbar 17=about 0.3λ

Dimension of the opening 17b along the intersecting width direction=about 2λ

The second IDT electrode 12 had the same or substantially the same design parameters as those of the first IDT electrode 11 except that no opening was provided in the fourth busbar 12a.

An acoustic wave device of a comparative example was obtained in the same or substantially the same manner as the acoustic wave device of the above-described example except that an opening was provided in the fourth busbar 12a and the fourth busbar 12a was configured in the same or substantially the same manner as the first busbar 11a.

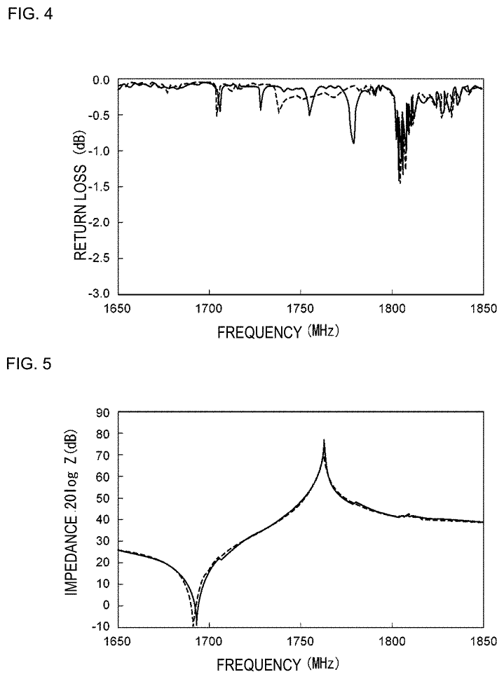

FIGS. 4 and 5 illustrate return loss characteristics and impedance characteristics as resonators of the acoustic wave devices according to the above example and the comparative example. In FIGS. 4 and 5, a broken line indicates the result of the comparative example, and a solid line indicates the result of the example.

As is clear from the return loss characteristics of FIG. 4, the return loss characteristics are significantly improved in, for example, the vicinity of about 1800 MHz to about 1820 MHz in the acoustic wave device of the example as compared with the acoustic wave device of the comparative example. Further, as illustrated in FIG. 5, it can be seen that the resonance characteristics are not significantly changed.

As illustrated in FIG. 4, it is considered that the return loss characteristics can be significantly improved in the vicinity of, for example, about 1800 MHz to about 1820 MHz because the frequency positions of the transverse mode generated in the first acoustic wave resonator unit 1 and the frequency position of the transverse modes generated in the second acoustic wave resonator unit 2 are different from each other. That is, in the comparative example, the return loss characteristics are greatly reduced in the vicinity of, for example, about 1800 MHz to about 1820 MHz due to the mutual strengthening of the transverse modes, whereas in the example, such deterioration of the characteristics are unlikely to occur.

In the acoustic wave device 10, the acoustic wave resonator is divided in series into the first and second acoustic wave resonator units. However, the acoustic wave resonator may be divided into three or more acoustic wave resonator units so as to include one or more third acoustic wave resonator units.

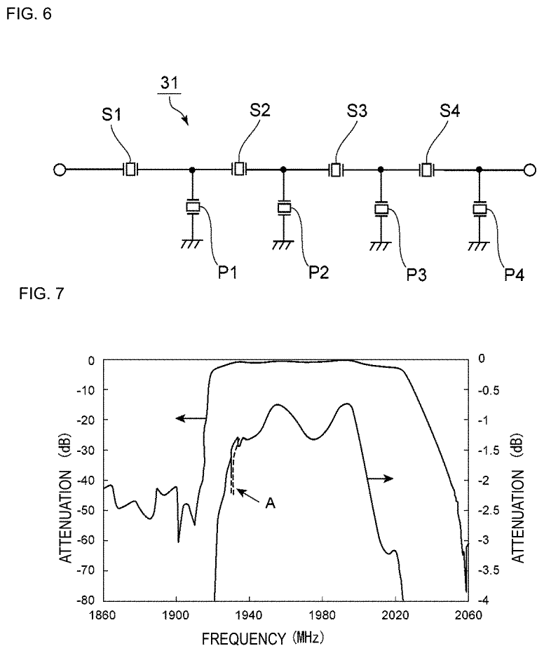

A ladder filter 31 illustrated in FIG. 6 is configured using the acoustic wave devices of the example and the comparative example described above. FIG. 6 is a circuit diagram of the ladder filter 31 in which the acoustic wave device 10 is preferably used.

In the ladder filter 31, a plurality of series arm resonators S1 to S4 are connected in series between input and output ends. The parallel arm resonators P1 to P4 are provided in a plurality of parallel arms connecting the series arms in which the series arm resonators S1 to S4 are provided and the ground potential.

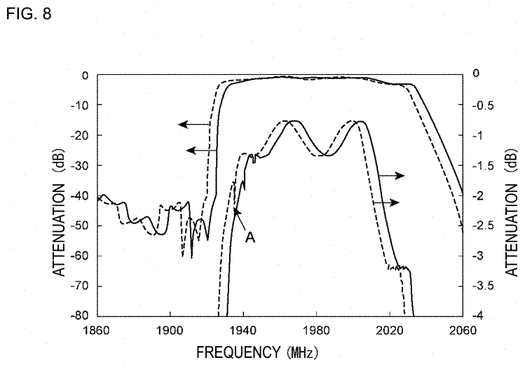

The acoustic wave devices of the example and the comparative example described above are used as the parallel arm resonators P1 to P4 and the series arm resonators S1 to S4 of the ladder filter 31. FIGS. 7 and 8 illustrate filter characteristics of a ladder filter including the acoustic wave device according to the example and a ladder filter including the acoustic wave device according to the comparative example.

In FIG. 7, a solid line represents the attenuation-frequency characteristics of the ladder filter including the acoustic wave device of the example, and the broken line represents the attenuation-frequency characteristics of the ladder filter including the acoustic wave device of the comparative example. Further, for ease of comparison, in FIG. 8, the attenuation-frequency characteristics of the ladder filter of the comparative example are illustrated by a broken line, and the attenuation-frequency characteristics of the ladder filter of the example are illustrated by being shifted from the original frequency position to the vicinity of about 5 MHz higher frequency. As is clear from FIGS. 7 and 8, in the ladder filter of the comparative example, a large ripple indicated by an arrow A appears in the pass band, whereas in the example, such a ripple does not appear. Therefore, it is understood that the filter characteristics of the ladder filter can be effectively improved by including the acoustic wave device according to the above-described example as the parallel arm resonator of the ladder filter.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
first and second acoustic wave resonator units;
a piezoelectric substrate;
a first IDT electrode on the piezoelectric substrate and defining the first acoustic wave resonator unit;
a second IDT electrode on the piezoelectric substrate and defining the second acoustic wave resonator unit electrically connected to the first acoustic wave resonator unit; and
an inter-stage connection portion connecting the first acoustic wave resonator unit and the second acoustic wave resonator unit; wherein
the first IDT electrode includes:
a first busbar;
a second busbar spaced apart from the first busbar;
a plurality of first electrode fingers extending toward the second busbar and including one ends connected to the first busbar; and
a plurality of second electrode fingers extending toward the first busbar and including one ends connected to the second busbar;
the second IDT electrode includes:
a third busbar;
a fourth busbar spaced apart from the third busbar;
a plurality of third electrode fingers extending toward the fourth busbar and including one ends connected to the third busbar; and
a plurality of fourth electrode fingers extending toward the third busbar and including one ends connected to the fourth busbar;
in each of the first and the second IDT electrodes, a central region is provided in a central portion of a direction in which the first and the second electrode fingers or the third and the fourth electrode fingers extend;
first and second low acoustic velocity regions in which acoustic velocities are lower than those in the central region are provided at both outer side portions of the central region in the direction in which the first and the second electrode fingers or the third and the fourth electrode fingers extend;
first and second high acoustic velocity regions in which acoustic velocities are higher than those in the central region are provided at both outer side portions of the first and second low acoustic velocity regions in the direction in which the first and the second electrode fingers or the third and the fourth electrode fingers extend;
in the first and the second high acoustic velocity regions in the first IDT electrode, a plurality of openings are provided along an acoustic wave propagation direction in both of the first and the second busbars;
of the third and the fourth busbars in the second IDT electrode, in the first high acoustic velocity region of the third busbar, a plurality of openings are provided along the acoustic wave propagation direction; and
in the fourth busbar, openings are not provided in the second high acoustic velocity region.

2. The acoustic wave device according to claim 1, wherein the first acoustic wave resonator unit and the second acoustic wave resonator unit are connected in series.

3. The acoustic wave device according to claim 1, wherein the piezoelectric substrate includes a high acoustic velocity member and a piezoelectric film laminated on the high acoustic velocity member, and the high acoustic velocity member is made of a high acoustic velocity material in which an acoustic velocity of a propagating bulk wave is higher than an acoustic velocity of an acoustic wave propagating through the piezoelectric film.

4. The acoustic wave device according to claim 3, wherein the high acoustic velocity member is a support substrate made of the high acoustic velocity material.

5. The acoustic wave device according to claim 3, further comprising a low acoustic velocity film laminated between the high acoustic velocity member and the piezoelectric film and made of a low acoustic velocity material in which an acoustic velocity of a propagating bulk wave is lower than an acoustic velocity of a bulk wave propagating through the piezoelectric film.

6. The acoustic wave device according to claim 3, further comprising a support substrate supporting the high acoustic velocity member.

7. The acoustic wave device according to claim 1, further comprising at least one acoustic wave resonator unit such that the acoustic wave device includes a plurality of acoustic wave resonator units including the first and the second acoustic wave resonator units.

8. The acoustic wave device according to claim 1, wherein the inter-stage connection portion defines and functions as the second busbar and the third busbar.

9. The acoustic wave device according to claim 1, wherein the plurality of openings in the first and second busbars and the plurality of openings in the third busbar are at least partially surrounded by the respective first, second, or third busbar.

10. The acoustic wave device according to claim 9, wherein at least one of the plurality of openings in the first and second busbars and the plurality of openings in the third busbar is entirely surrounded by the respective first, second, or third busbar.

11. The acoustic wave device according to claim 1, wherein the plurality of openings in the first and second busbars and the plurality of openings in the third busbar are entirely surrounded by the respective first, second, or third busbar.

12. The acoustic wave device according to claim 1, wherein the first busbar includes an inner busbar portion, an outer busbar portion, and a linking portion connecting the inner busbar portion and the outer busbar portion.

13. The acoustic wave device according to claim 1, further comprising a common busbar including a portion of the first busbar and a portion of the second busbar.

14. The acoustic wave device according to claim 6, wherein the support substrate includes a semiconductor or an insulator.

15. The acoustic wave device according to claim 14, wherein the semiconductor includes silicon.

16. The acoustic wave device according to claim 14, wherein the insulator includes Al₂O₃.

17. The acoustic wave device according to claim 3, wherein the high acoustic velocity member includes at least one of aluminum oxide, silicon carbide, silicon nitride, silicon oxynitride, silicon, sapphire, lithium tantalate, lithium niobate, crystal, alumina, zirconia, cordierite, mullite, steatite, forsterite, magnesia, a diamond-like carbon (DLC) film, or diamond.

18. The acoustic wave device according to claim 5, wherein the low acoustic velocity film includes at least one of silicon oxide, glass, silicon oxynitride, tantalum oxide, a compound obtained by adding fluorine, carbon, boron, hydrogen, or a silanol group to silicon oxide.
